(19) United States
(12) Patent Application Publication
(10) Pub. No.: US 2010/0124673 A1
(43) Pub. Date: May 20, 2010

(54) HIGH DENSITY MAGNETIC RECORDING FILM AND METHOD FOR MANUFACTURING THE SAME BY USING RAPID THERMAL ANNEALING TREATMENT

(75) Inventors: Sheng-Chi Chen, Taipei City (TW); Po-Cheng Kuo, Taipei City (TW); Chi-Long Shen, Shulin City (TW); Sung-po Chen, Pingjhen City (TW); Ching-Ray Chang, Taipei City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Sheng-Chi Chen, Taipei City (TW)

(21) Appl. No.: 12/408,070

(22) Filed: Mar. 20, 2009

(30) Foreign Application Priority Data
Nov. 18, 2008 (TW) 097144598

(51) Int. Cl. G11B 5/65; H01F 1/00; C23C 14/34

(52) U.S. Cl. 428/836.1; 148/121; 204/192.2

(57) ABSTRACT

A high density magnetic recording film by using a rapid thermal annealing process is provided. The high density magnetic recording film includes a substrate; and a ferromagnetic layer formed on the substrate; wherein the rapid thermal annealing process is performed for the ferromagnetic layer at a temperature range of 600 to 800° C. for 5 to 180 seconds with a heating ramp rate of 60 to 100° C./sec so as to obtain the high density magnetic recording film.

### FIELD OF THE INVENTION

The present invention relates to a high density magnetic recording film and the method for manufacturing the same, and more particularly to a high density magnetic recording film and the method for manufacturing the same by using the rapid thermal annealing treatment.

### BACKGROUND OF THE INVENTION

The recording density of the magnetic recording medium is inversely proportional to the size of the magnetic particle. The smaller the size of the magnetic particle is, the higher the recording density of the magnetic recording film is. According to the Stoner-Wohlfarth model, the minimum thermal stable grain size (Dp) of a magnetic recording medium with a life of ten years is (60 K_{B}T/Kᵤ)^{1/3}, wherein Kᵤ is the magnetocrystalline anisotropy constant, K_{B} is the Boltzmann constant and T is the absolute temperature. Currently, the material of the most commonly used recording medium for the hard disk is the CoCrPtM alloy film (M=B, Ni, Ta or W), whose Ku is about 2×10⁶ erg/cm³. Therefore, when the size of the magnetic particle of the CoCrPtM alloy film is smaller than 10 nm, the thermal stability thereof will be deteriorated. The Kᵤ of the ordering L1₀FePt hard phase is up to 7×10⁷ erg/cm³, and according to theory, the minimum thermal stable grain size thereof can be minimized to 3 nm. Hence, the FePt alloy film is promising to replace the current CoCrPt alloy film to become the mainstream material of the ultrahigh density magnetic recording medium in the next generation.

However, the as-deposited FePt alloy film presents a disordering γ-FePt soft phase, which will only be transferred into an ordering L1₀FePt hard phase after a thermal treatment of above 500° C. Since the ordering temperature is so high, it is hard to avoid the issue of grain coarsening. Therefore, how to promote the degree of ordering to enhance the coercivity (Hc) has become the major topic in the study of FePt alloy film in recent years.

It is found that the ordering temperature can be effectively reduced to enhance the coercivity by adding the third element Cu to the FePt alloy film, but the FePt grain would be enlarged. Comparatively, although the addition of some third element (e.g. Ag or Cr) can reduce the FePt grain size, the ordering temperature will be increased which results in the decrease of the coercivity. Hence, a thermal treatment for the nano grain alloy particle which can enhance the coercivity and reduce the grain size of the recording film is required, so as to manufacture the ultrahigh density recording medium.

In order to overcome the drawbacks in the prior art, a high density magnetic recording film and the method for manufacturing the same by using the rapid thermal annealing treatment are provided. The particular design in the present invention not only solves the problems described above, but also is easy to be implemented. Thus, the present invention has the utility for the industry.

### SUMMARY OF THE INVENTION

In accordance with one aspect of the present invention, a high density magnetic recording film by using a rapid thermal annealing process is provided. The high density magnetic recording film includes a substrate; and a ferromagnetic layer formed on the substrate; wherein the rapid thermal annealing process is performed for the ferromagnetic layer at a temperature range of 600 to 800° C. for 5 to 180 seconds with a heating ramp rate of 60 to 100° C./sec so as to obtain the high density magnetic recording film.

Preferably, the rapid thermal annealing process is performed under a protection gas of argon (Ar).

Preferably, the substrate is one of a glass substrate and a silicon substrate.

Preferably, the ferromagnetic layer is made of a Fe-based alloy.

Preferably, the Fe-based alloy is a FePt alloy.

Preferably, the ferromagnetic layer is formed on the substrate by a magnetron sputtering.

Preferably, a thickness of the ferromagnetic layer is 30 nm.

Preferably, a coercivity of the high density magnetic recording film is larger than 6000 Oe.

Preferably, the high density magnetic recording film has isolated magnetic domains with each other.

In accordance with another aspect of the present invention, a method for manufacturing a high density magnetic recording film is provided. The method includes steps of providing a magnetic recording film; and performing a rapid thermal annealing process for the magnetic recording film so as to obtain the high density magnetic recording film.

Preferably, the magnetic recording film includes a substrate and a ferromagnetic layer.

Preferably, the substrate is one of a glass substrate and a silicon substrate.

Preferably, the ferromagnetic layer is formed on the substrate by a magnetron sputtering.

Preferably, the ferromagnetic layer is made of a Fe-based alloy.

Preferably, the Fe-based alloy is a FePt alloy.

Preferably, a thickness of the ferromagnetic layer is 30 nm.

Preferably, a coercivity of the high density magnetic recording film is larger than 6000 Oe.

Preferably, the high density magnetic recording film has plural magnetic domains isolated with each other.

Preferably, the rapid thermal annealing process has a heating ramp rate ranged from 60 to 100° C./sec.

Preferably, the rapid thermal annealing process has an annealing temperature range from 600 to 800° C.

Preferably, the rapid thermal annealing process has an annealing time ranged from 5 to 180 seconds.

Preferably, the rapid thermal annealing process is performed under a protection gas of argon.

In accordance with a further aspect of the present invention, a method for manufacturing a high density magnetic recording film is provided. The method includes steps of providing a substrate; forming a ferromagnetic layer on the substrate; and performing a rapid thermal annealing process for the ferromagnetic layer so as to obtain the high density magnetic recording film.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 shows the structure of the high density magnetic recording film according to a preferred embodiment of the present invention;

FIGS. 2A-2D show the hysteresis curves of the magnetic recording films of the present invention and the comparative examples after annealing;

FIG. 3A shows the relationship between the coercivity and the heating ramp rate where the 30 nm FePt alloy film is heated to 700° C. for 3 minutes with different heating ramp rates;

FIG. 3B shows the relationship between the coercivity and the annealing temperature where the 30 nm FePt alloy film is heated to different temperatures for 3 minutes with a heating ramp rate of 100° C./sec; and

FIG. 3C shows the relationship between the coercivity and the annealing time where the 30 nm FePt alloy film is heated to 700° C. for different time with a heating ramp rate of 100° C./sec.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

The present invention provides a high density magnetic recording film by using the rapid thermal annealing treatment. The high density magnetic recording film includes a substrate and a ferromagnetic layer. The substrate is a glass substrate or a silicon substrate, and the ferromagnetic layer is formed on the substrate by direct current magnetron sputtering. The ferromagnetic layer is a Fe-based alloy, preferably a 30 nm FePt alloy. A rapid thermal annealing process is performed for the as-deposited FePt alloy film at a temperature range of 600 to 800° C. for 5 to 180 seconds with a heating ramp rate of 60 to 100° C./sec, wherein the rapid thermal annealing process is performed under the protection gas of argon (Ar). The high density magnetic recording film after the rapid thermal annealing process has a coercivity larger than 6000 Oe and isolated magnetic domains with each other, which has potential for the high density magnetic recording medium.

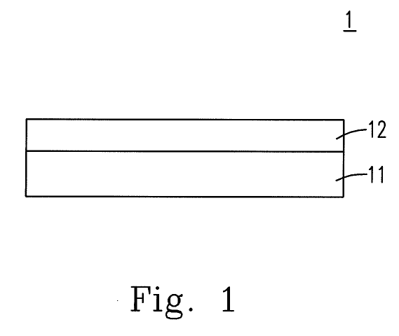

Please refer to FIG. 1, which shows the structure of the high density magnetic recording film according to a preferred embodiment of the present invention. According to FIG. 1, the high density magnetic recording film 1 of the present invention includes a substrate 11 and a ferromagnetic layer 12. The substrate 11 is made of glass or silicon, and the ferromagnetic layer 12 is formed on the substrate 11 by direct current magnetron sputtering. The material of the ferromagnetic layer 12 is selected from Fe-based alloys, preferably a 30 nm FePt alloy. The content of Fe in the FePt alloy is 40-60 at %, preferably Fe₅₀Pt₅₀.

According to FIG. 1, the high density magnetic recording film 1 of the present invention includes a silicon substrate 11 and a 30 nm FePt ferromagnetic layer 12. The sputtering power for the 30 nm FePt ferromagnetic layer 12 is controlled at 50 watt for Fe and 10 watt for Pt. The Ar pressure in the sputtering chamber is fixed at 10 mTorr, and the rotation rate of the silicon substrate 11 is fixed at 10 rpm. The as-deposited film is annealed in a rapid thermal annealing furnace with the protection gas of Ar at the temperature range of 600 to 800° C. for 5 to 180 seconds with the heating ramp rate of 60 to 100° C./sec and then cooled, so that an ordering L1₀FePt hard phase having a face-centered tetragonal crystal structure with a high magnetocrystalline anisotropy constant is generated, thereby obtaining a high performance magnetic recording alloy film.

The magnetic property of the FePt alloy film of the present invention is measured by the vibrating sample magnetometer (VSM), the crystal structure thereof is identified by Cu-Kα of the X-ray diffrationmeter (XRD), the surface appearance thereof is observed by the atomic force microscope (AFM), and the distribution of magnetic domains is observed by the magnetic force microscope (MFM).

### Embodiment

The as-deposited 30 nm FePt alloy film is annealed in a rapid thermal annealing furnace with the protection gas of Ar at 700° C. for 180 seconds with the heating ramp rate of 100° C./sec and then cooled.

### COMPARATIVE EXAMPLE 1

The as-deposited 30 nm FePt alloy film is annealed in a rapid thermal annealing furnace with the protection gas of Ar at 700° C. for 180 seconds with the heating ramp rate of 20° C./sec and then cooled.

### COMPARATIVE EXAMPLE 2

The as-deposited 30 nm FePt alloy film is annealed in a rapid thermal annealing furnace with the protection gas of Ar at 500° C. for 180 seconds with the heating ramp rate of 100° C./sec and then cooled.

### COMPARATIVE EXAMPLE 3

The as-deposited 30 nm FePt alloy film is annealed in a rapid thermal annealing furnace with the protection gas of Ar at 700° C. for 1 second with the heating ramp rate of 100° C./sec and then cooled.

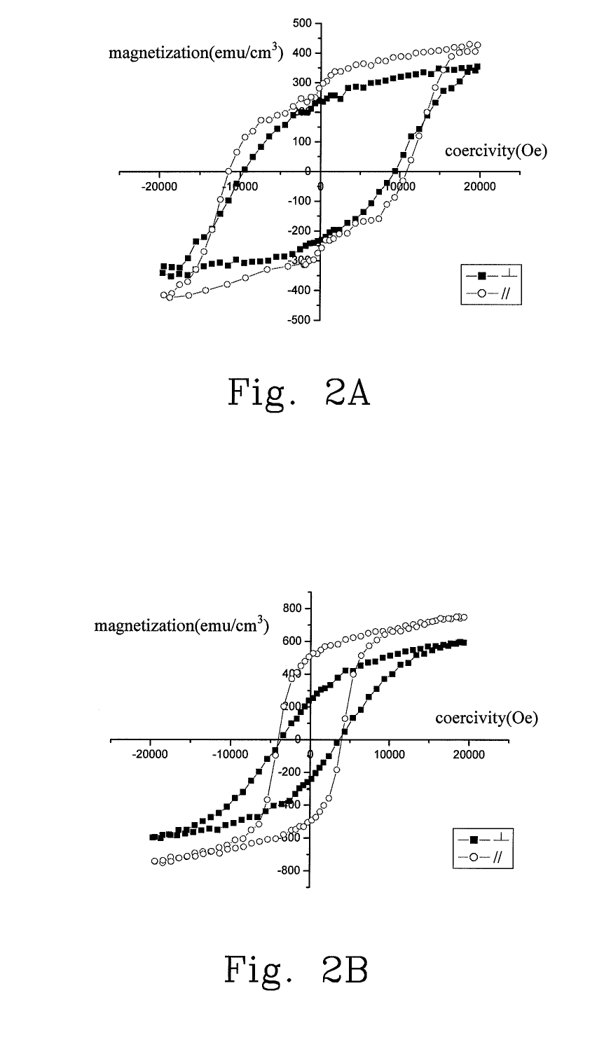

Please refer to FIGS. 2A-2D, which show the hysteresis curves of the magnetic recording films of the present invention and the comparative examples after annealing. It can be found in FIGS. 2A and 2B that since the time required for heating to 700° C. with the heating ramp rate of 100° C./sec is shorter, the time for grain growth is relatively reduced, so that smaller grains can be obtained which enhances the coercivity (Hc). The coercivity of the FePt alloy film with the heating ramp rate of 100° C./sec is above 9.5 kOe, which has potential for the ultrahigh density magnetic recording medium. Compared with FIG. 2B, it can be found that when the heating ramp rate is 20° C./sec, the coercivity is only about 4 kOe.

Please refer to FIG. 2C. When the annealing temperature is 500° C., the coercivity is only several hundreds Oe. Compared with FIG. 2A, when the annealing temperature is raised to 700° C., the coercivity is increased apparently. It can be known from the measurement of the magnetic property that when the annealing temperature is below 500° C., most of the FePt alloy film present a disordering γ-FePt soft phase; when the annealing temperature reaches 700° C., the proportion of the disordering γ-FePt soft phase being converted into an ordering L1₀-FePt hard phase will be significantly enhanced.

Please refer to FIG. 2D. When the annealing time is 1 second, the coercivity is almost zero. This is because the annealing time is too short which makes the disordering γ-FePt soft phase unable to be converted into the ordering L1₀-FePt hard phase, so that the hysteresis curve presents a soft magnetic property. Compared with FIG. 2A, when the annealing time is 180 seconds, there is enough time for the disordering γ-FePt soft phase to be completely converted into the ordering L1₀-FePt hard phase, so that the coercivity is significantly enhanced.

According to the high density magnetic recording film by using the rapid thermal annealing treatment of the present invention, the coercivity of the 30 nm FePt alloy film annealed at 700° C. for 180 seconds with the heating ramp rate of 100° C./sec is significantly enhanced, compared with that annealed with the heating ramp rate of 20° C./sec. Besides, raising the heating ramp rate also helps to obtain smaller FePt magnetic particles, and the magnetic domains will also be more isolated with each other. This helps to enhance the magnetic recording density and reduce the medium noise, which has potential for the ultrahigh density magnetic recording medium. Moreover, a larger coercivity will only be obtained when the annealing temperature is higher than 500° C. Apparently, in order to convert the disordering γ-FePt soft phase into the ordering L1₀-FePt hard phase, the annealing temperature needs to be higher than 500° C. to overcome the activation energy for phase transformation. Furthermore, the coercivity will only be significantly increased when the annealing time is larger than 1 second. Therefore, in order to transfer the disordering γ-FePt soft phase into the ordering L1₀-FePt hard phase, the annealing time also needs to be larger than 1 second.

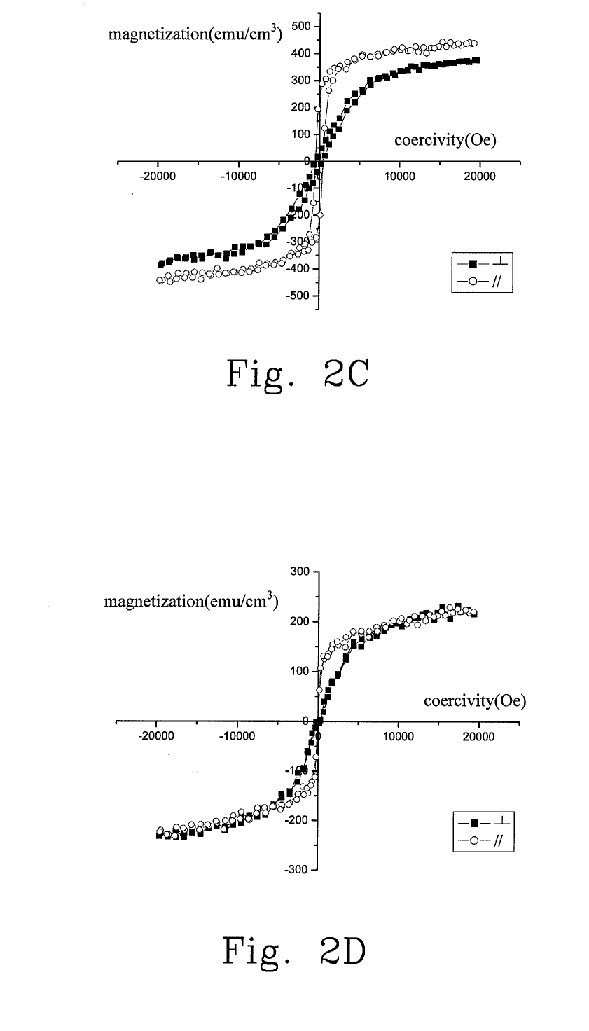

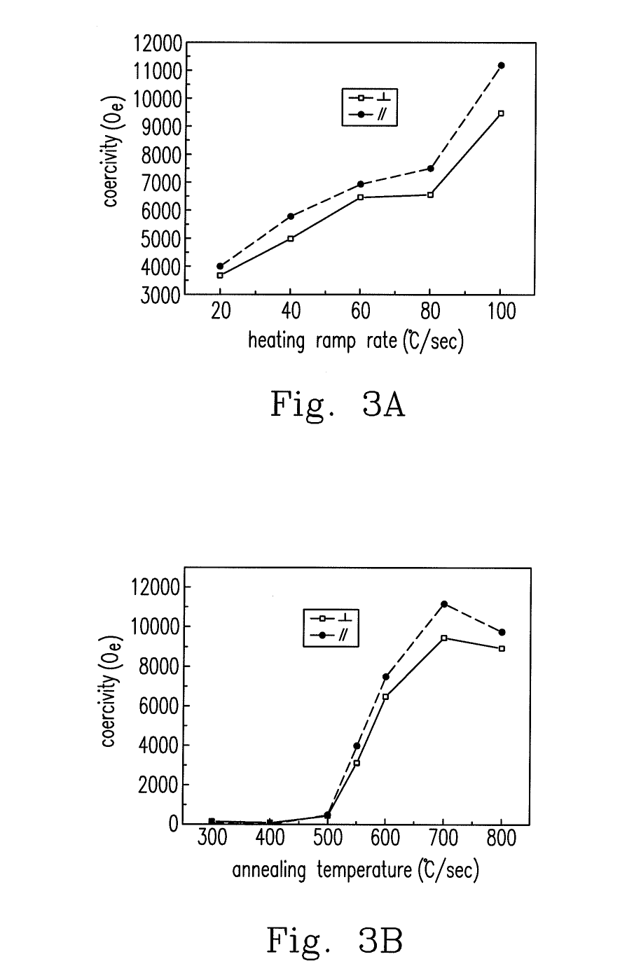

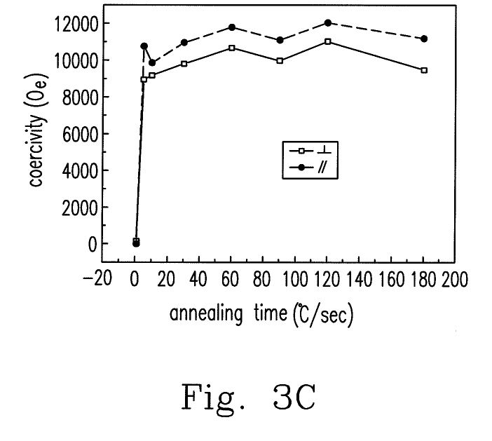

Please refer to FIG. 3A, which shows the relationship between the coercivity and the heating ramp rate where the 30 nm FePt alloy film is heated to 700° C. for 3 minutes with different heating ramp rates. As shown in FIG. 3A, when the heating ramp rate is between 60-100° C./sec, the coercivity of the FePt alloy film is larger than 6000 Oe.

Please refer to FIG. 3B, which shows the relationship between the coercivity and the annealing temperature where the 30 nm FePt alloy film is heated to different temperatures for 3 minutes with a heating ramp rate of 100 ° C./sec. As shown in FIG. 3B, when the annealing temperature is between 600-800° C., the coercivity of the FePt alloy film is larger than 600 Oe.

Please refer to FIG. 3C, which shows the relationship between the coercivity and the annealing time where the 30 nm FePt alloy film is heated to 700° C. for different time with a heating ramp rate of 100° C./sec. As shown in FIG. 3C, when the annealing time is between 5-180 seconds, the coercivity of the FePt alloy film is larger than 6000 Oe.

Based on the above, the present invention effectively solves the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A high density magnetic recording film by using a rapid thermal annealing process, comprising:
a substrate; and
a ferromagnetic layer formed on the substrate;
wherein the rapid thermal annealing process is performed for the ferromagnetic layer at a temperature range of 600 to 800° C. for 5 to 180 seconds with a heating ramp rate of 60 to 100° C./sec so as to obtain the high density magnetic recording film.

2. A high density magnetic recording film as claimed in claim 1, wherein the rapid thermal annealing process is performed under a protection gas of argon (Ar).

3. A high density magnetic recording film as claimed in claim 1, wherein the substrate is one of a glass substrate and a silicon substrate.

4. A high density magnetic recording film as claimed in claim 1, wherein the ferromagnetic layer is made of a Fe-based alloy.

5. A high density magnetic recording film as claimed in claim 4, wherein the Fe-based alloy is a FePt alloy.

6. A high density magnetic recording film as claimed in claim 1, wherein the ferromagnetic layer is formed on the substrate by a magnetron sputtering.

7. A high density magnetic recording film as claimed in claim 1, wherein a thickness of the ferromagnetic layer is 30 nm.

8. A high density magnetic recording film as claimed in claim 1, wherein a coercivity of the high density magnetic recording film is larger than 6000 Oe.

9. A high density magnetic recording film as claimed in claim 1, wherein the high density magnetic recording film has isolated magnetic domains with each other.

10. A method for manufacturing a high density magnetic recording film, comprising steps of:
providing a magnetic recording film; and
performing a rapid thermal annealing process for the magnetic recording film so as to obtain the high density magnetic recording film.

11. A method as claimed in claim 10, wherein the magnetic recording film includes a substrate and a ferromagnetic layer.

12. A method as claimed in claim 11, wherein the substrate is one of a glass substrate and a silicon substrate.

13. A method as claimed in claim 1, wherein the ferromagnetic layer is formed on the substrate by a magnetron sputtering.

14. A method as claimed in claim 11, wherein the ferromagnetic layer is made of a Fe-based alloy.

15. A method as claimed in claim 14, wherein the Fe-based alloy is a FePt alloy.

16. A method as claimed in claim 11, wherein a thickness of the ferromagnetic layer is 30 nm.

17. A method as claimed in claim 10, wherein a coercivity of the high density magnetic recording film is larger than 6000 Oe.

18. A method as claimed in claim 10, wherein the high density magnetic recording film has isolated magnetic domains with each other.

19. A method as claimed in claim 10, wherein the rapid thermal annealing process has a heating ramp rate ranged from 60 to 100° C./sec.

20. A method as claimed in claim 10, wherein the rapid thermal annealing process has an annealing temperature range from 600 to 800° C.

21. A method as claimed in claim 10, wherein the rapid thermal annealing process has an annealing time ranged from 5 to 180 seconds.

22. A method as claimed in claim 10, wherein the rapid thermal annealing process is performed under a protection gas of argon.

23. A method for manufacturing a high density magnetic recording film, comprising steps of:
providing a substrate;
forming a ferromagnetic layer on the substrate; and
performing a rapid thermal annealing process for the ferromagnetic layer so as to obtain the high density magnetic recording film.
